(19) United States
(12) Patent Application Publication
(10) Pub. No.: US 2010/0271147 A1
(43) Pub. Date: Oct. 28, 2010

(54) LOW-POWER PIEZOELECTRIC AMPLIFIER AND METHOD THEREOF

(75) Inventor: Vadim Leibman, Migdal Ha'emek (IL)

Correspondence Address: MARSTELLER & ASSOCIATES, P O BOX 803302, DALLAS, TX, 75380-3302, US

(73) Assignee: AUDIODENT ISRAEL, LTD., Omer (IL)

(21) Appl. No.: 12/743,351

(22) PCT Filed: Nov. 20, 2008
(86) PCT No.: PCT/IL08/01530

§ 371 Date: May 17, 2010

(30) Foreign Application Priority Data
Nov. 21, 2007 (IL) 187544

(51) Int. Cl. H03B 5/36

(52) U.S. Cl. 331/160

(57) ABSTRACT

The invention relates to a switched low-energy consumption amplifier for a piezoelectric element, which comprises: (a) an inductor, which together with the capacitance of said piezoelectric element forms an LC circuit; (b) a battery connected to said LC circuit; (c) a set of controlled switches capable of connecting and disconnecting circuit components at a rate which is significantly higher than the frequency of an input signal to said circuit; (d) a comparator for receiving an input signal, comparing a present voltage value of the input signal with a present voltage value over said piezoelectric element or a part, thereof, and conveying an indication regarding said comparison to a switching control unit; and (e) a switching control unit for receiving said indication from said comparator, and determining repeatedly every period P, which is significantly shorter than the period of the highest frequency included within said input signal, whether the piezoelectric element should be charged or discharged, and accordingly providing a control signal to each of said controlled switches with a certain duty cycle of P, thereby causing energy transfer from the piezoelectric element to the inductor and/or battery, or from the battery and/or inductor to the piezoelectric element, thereby retaining the energy within the amplifier circuit.

### FIELD OF THE INVENTION

The present invention relates to piezoelectric amplifiers. More particularly, the invention relates to providing a low-power piezoelectric driver, having an increased efficiency and gain, and providing a method thereof.

### DEFINITIONS, ACRONYMS AND ABBREVIATIONS

Throughout this specification, the following definitions are employed:

Piezoelectric actuator: is a piezoelectric element that is used for converting an electrical signal into a mechanical displacement.

Piezoelectric amplifier: is an electronic circuitry that provides amplification and boosts regulation that is required to drive piezoelectric elements, such as a piezoelectric actuator, piezoelectric speaker, etc. Such piezoelectric amplifier is also commonly referred to in the art as a piezoelectric driver. Therefore, the terms “driver” and “amplifier” are used herein exchangably.

Piezoelectric speaker: is a piezoelectric element in which an electric signal is converted into a sound pressure, thus generating a sound. Piezoelectric speakers are commonly used in numerous applications, such as portable computers, hearing instruments, medical devices and many others.

### BACKGROUND OF THE INVENTION

In the last years, the usage of piezoelectric elements has dramatically increased. According to the prior art, piezoelectric elements are used in a wide range of mechatronic applications (e.g., fuel injectors) and in many electronic devices, such as portable computers, medical devices and many others. For operating the piezoelectric elements (such as a piezoelectric actuator or piezoelectric speaker), a piezoelectric driver is required. However, current piezoelectric drivers consume relatively high electrical power. This becomes a significant problem in devices, such as hearing aids or other miniature medical devices, in which power sources (batteries) are limited due to a small size of the device, or where replacing the batteries is difficult or even prohibitive. Further, the cost of small and highly efficient batteries can be significant, thus preventing the user from replacing them frequently.

Usually, power sources, such as batteries, are optimized for use with devices having a passive resistance response, such as conventional amplifiers or displays. However, piezoelectric speakers act as capacitors, and therefore connecting a piezoelectric speaker to a power source, such as a battery, results in loss of the power source energy and poor efficiency. An exemplary prior art circuitry 100 of a piezoelectric amplifier/driver for driving a piezoelectric speaker element 105 is shown in FIG. 1. When the amplitude of an input signal increases, the voltage on piezoelectric speaker 105 is also increased, and its piezoelectric capacitor is charged. In order to minimize delays for providing an output audio signal, high current is used for decreasing the piezoelectric capacitor charge time, thus consuming significant battery power. Moreover, upon an increase of the input signal amplitude, the higher current is drawn from the battery, yet, the voltage on the piezoelectric capacitor still lags after the input voltage (due to the charge time of said piezoelectric capacitor). The voltage difference falls on internal components of circuitry 100 (e.g., resistors R₁ to R₄, amplifier 1, amplifier 2), thus wasting battery resources. Similarly, when the input voltage decreases, the piezoelectric capacitor is discharged, and the power is wasted due to the high discharge current and due to the voltage differences between the piezoelectric capacitor and the input signal.

In addition, piezoelectric speakers typically operate under relatively high voltage levels (e.g., 30 Volts) in order to generate an audible sound. Therefore, such piezoelectric speakers require a voltage converter or a “charge pump” in order to operate within battery-powered devices, which results in a further increase of power consumption.

Providing an efficient low-power piezoelectric driver can dramatically reduce battery consumption, and allow and/or increase the usage of piezoelectric speakers in miniature applications, such as hearing aids.

Therefore, there is a continuous need to overcome the prior art drawbacks.

It is an object of the present invention to provide a low-power piezoelectric driver, significantly reducing power (battery) consumption.

It is another object of the present invention to increase efficiency and gain of a piezoelectric driver.

It is still another object of the present invention to provide a low-power piezoelectric driver for use in miniature devices, such as hearing aids.

It is still another object of the present invention to provide a low-power piezoelectric driver that eliminates the need for using a voltage converter or a “charge pump”.

Other objects and advantages of the invention will become apparent as the description proceeds.

### SUMMARY OF THE INVENTION

Hereinafter, when the term “piezoelectric amplifier” is mentioned, it should be understood that it refers also to the term “piezoelectric driver”. Also, wherein the term connected is mentioned, it should be understood that it refers to a direct connection, or to an indirect connection through any unit or component (active, passive or other), such as a resistor, etc.

The present invention relates to providing a low-power piezoelectric amplifier, having an increased efficiency and gain, and providing a method thereof.

The invention relates to a switched low-energy consumption amplifier for a piezoelectric element, which comprises: (a) an inductor, which together with the capacitance of said piezoelectric element forms an LC circuit; (b) a battery connected to said LC circuit; (c) a set of controlled switches capable of connecting and disconnecting circuit components at a rate which is significantly higher than the frequency of an input signal to said circuit; (d) a comparator for receiving an input signal, comparing a present voltage value of the input signal with a present voltage value over said piezoelectric element or a part thereof, and conveying an indication regarding said comparison to a switching control unit; and (e) a switching control unit for receiving said indication from said comparator, and determining repeatedly every period P, which is significantly shorter than the period of the highest frequency included within said input signal, whether the piezoelectric element should be charged or discharged, and accordingly providing a control signal to each of said controlled switches with a certain duty cycle of P, thereby causing energy transfer from the piezoelectric element to the inductor and/or battery, or from the battery and/or inductor to the piezoelectric element, thereby retaining the energy within the amplifier circuit.

Preferably, (a) if it is determined by said switching control unit that the piezoelectric element should be charged, initially providing a first set of control signals to said controlled switches which results in charging of the inductor from said battery during a period t₁, followed by the providing of a second set of control signals which results in transfer of said charge during a period t₂ from the inductor to said piezoelectric element, and wherein t₁+t₂≦P; or (b) if it is found by said switching control unit that the piezoelectric element should be discharged, initially providing a third set of control signals to said controlled switches which results in transfer of charge from said piezoelectric element to the inductor and battery during a period t₃, followed by the providing of a fourth set of control signals which results in transfer of charge during a period t₄ from the piezoelectric element to the inductor only, and wherein t₃+t₄≦P.

In another aspect, (c) if it is determined by said switching control unit that the piezoelectric element should be negatively charged, initially providing a 5^{th} set of control signals to said controlled switches which results in transfer of charge from the battery to the inductor during a period t₅, followed by the providing of a 6^{th} set of control signals which results in a transfer of charge from the piezoelectric element to the inductor during a time period t₆, and wherein t₅+t₆≦P; or (d) if it is determined by said switching control unit that the piezoelectric element should be negatively discharged, initially providing an 7^{th} set of control signals to said controlled switches which results in transfer of charge from the piezoelectric element to the ground a period t₇, followed by the providing of an 8^{th} set of control signals which results in terminating a transfer of charge from the piezoelectric element to the ground during a time period t₈, and wherein t₇+t₈≦P.

Preferably, the piezoelectric element is a piezoelectric speaker.

Preferably, the period P is at least 10 times shorter than the period of the highest frequency included within said input signal.

Preferably, the amplifier further comprises diodes.

Preferably, said switches are semiconductor switches.

Preferably, the amplifier further comprises safety measures against transient extreme voltage levels which may harm the circuit components.

### BRIEF DESCRIPTION OF THE DRAWINGS

In the drawings:

FIG. 1 is an exemplary circuitry of a piezoelectric amplifier/driver for driving a piezoelectric speaker element, according to the prior art;

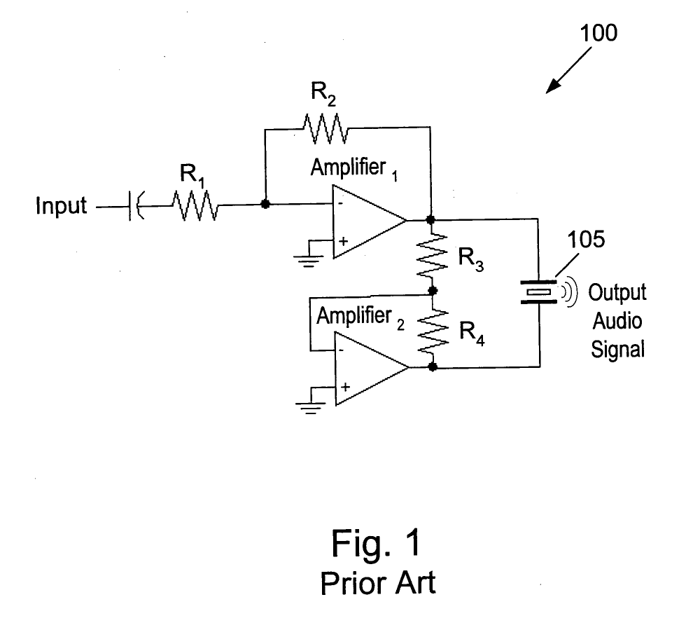

FIG. 2A is an exemplary circuitry of a low-power piezoelectric driver having an increased efficiency and gain, and having relatively low power consumption, according to an embodiment of the present invention;

FIG. 2B is a circuitry of a low-power piezoelectric driver of FIG. 2A, wherein switches S₁, S₃ and S₄ are closed and switch S₂ is open, according to an embodiment of the present invention;

FIG. 2C is a circuitry of a low-power piezoelectric driver of FIG. 2A, wherein switches S₁, S₃ are closed and switches S₂, S₄ are open, according to an embodiment of the present invention;

FIG. 2D is a circuitry of a low-power piezoelectric driver of FIG. 2A, wherein switches S₂, S₄ are closed, switch S₃ is open and switch S₁ is time-controlled, according to an embodiment of the present invention;

FIG. 3 is an exemplary graph presenting voltage amplitude on a piezoelectric speaker, when the input voltage is a sine signal and a low clock rate control signals are provided to switches of the circuitry, according to an embodiment of the present invention;

FIG. 4 is an exemplary graph presenting voltage amplitude on a piezoelectric speaker when the input voltage is a sine signal, and a high clock rate control signals are provided to switches of the circuitry, according to an embodiment of the present invention; and

FIG. 5 is an exemplary flow chart which describes the method of implementation in an embodiment of the present invention.

### DETAILED DESCRIPTION OF PREFERRED EMBODIMENTS

The present invention relates to a low-power electronic circuitry that increases efficiency and gain of a piezoelectric driver and reduces its power consumption (especially, in audio frequencies from 200 Hz (Hertz) to 10 KHz (KiloHertz)) by creating a switched inductive compensation to the capacitance of a piezoelectric element (for example, a piezoelectric speaker). The electronic circuitry creates inductive compensation to the capacitance of the piezoelectric element, according to the piezoelectric element impedance, whereas electric charge is transferred between the piezoelectric element, the inductor and the power source (battery), thus retaining the energy that is accumulated in the piezoelectric element within the circuit.

The compensation circuitry of the present invention forms an LC circuit, in which the “C” is represented by the capacitance of the piezoelectric element. The invention assumes that the input signal to the piezoelectric element has some highest relevant frequency of interest which is known. For example, when dealing with a piezoelectric element that serves as a speaker, said highest frequency may be about 10 KHz. The energy compensation by the circuit of the present invention is performed periodically by small amounts, at a rate which is significantly higher than the highest frequency of the input signal. For example, if the highest relevant frequency of the input signal is 10 KHz, the compensations according to the present invention are performed at a frequency much higher, for example that is 10 times higher than the highest relevant frequency of the input signal, in this example at a frequency of 100 KHz or more. In other words, assuming that the highest relevant input signal is 10 KHz, the period by which the present invention operates is 10 μsec or shorter. The operation period of the circuitry of the present invention will be referred to herein as P. As will be shown, the apparatus of the present invention not only conserves energy in comparison to the prior art arrangements, but it also “amplifies” the input signal to a level that can operate the piezoelectric element. For example, the circuitry of the present invention can receive an input signal of about 0.1V peak to peak, and can provide to the piezoelectric element a signal of 30V peak to peak.

As will also be demonstrated, the circuitry of the present invention comprises said LC circuit (where the “C” represents the capacitance of the piezoelectric element), a comparator, several switches and diodes, a control unit for controlling said switches and a battery.

The embodiments that are described herein relate to a case where the piezoelectric element is operated by positive voltage (e.g. 0V to 60Vp-p). It should be noted, however, that a same embodiment, with a few straight forward modifications can be used in cases where the piezoelectric element operates on positive and negative voltage (e.g.+/−30Vp-p).

Immediately at the beginning of each period P, the comparator compares between the present voltage level over the piezoelectric element (or a division thereof) and the input signal. The comparator conveys the result of the comparison to the switching control unit. The switching control unit, in turn, determines whether the voltage over the piezoelectric element is higher than necessary or lower than necessary, or more particularly, whether the charge within the piezoelectric element is higher or lower than has to be in view of the input signal. If the charge over the piezoelectric element is found to be lower than necessary, the switching control unit closes switches in such a manner that initially cause transfer of charge from the battery to the inductor. After a certain time period t₁, but still during said period P, the switching control unit changes the setting of the switches such that the charge within the inductor, as accumulated, is transferred to the piezoelectric element during period t₂, which is the remaining part of P. If, on the other hand, the charge over the piezoelectric element is found to be higher than necessary, the switching control unit closes switches in such a manner that initially causes transfer of charge from the piezoelectric element to the inductor L and the battery. After a certain time period t₃, but still during said period P, the switching control unit changes the setting of the switches such that the charge within the piezoelectric element transfers to the inductor only during period t₄. As said, one of said two optional operations are performed during each period P (wherein P≧t₁+t₂≧t₃+t₄), depending on the voltage level presently found to be on the piezoelectric element (which reflects the amount of charge within said element) and on the present level of the input signal. Said process is repeated each period P (or in other words, many times during the expected period of the highest relevant frequency of the input signal), and one of said two options is initiated accordingly. Therefore, in such a manner a significant amount of energy is conserved within the circuit, and furthermore, the signal over the piezoelectric element is significantly amplified in comparison to the input signal.

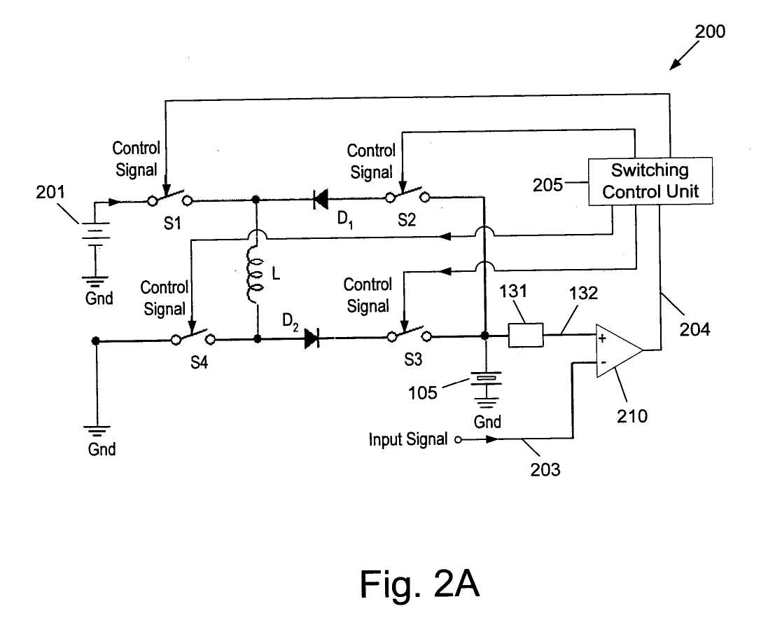

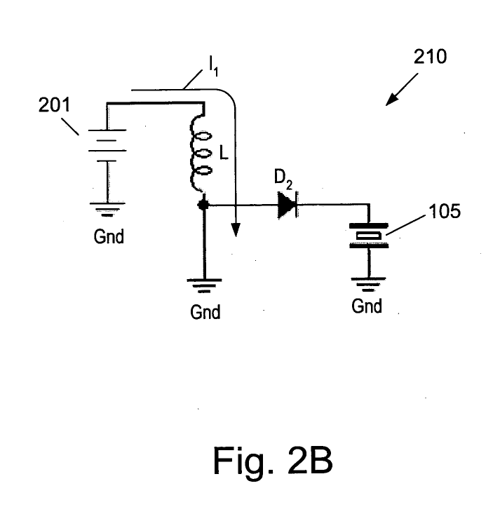

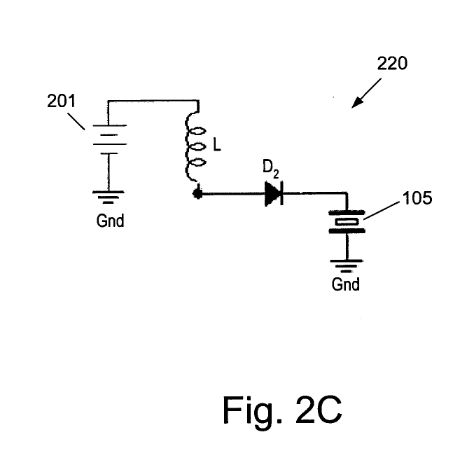

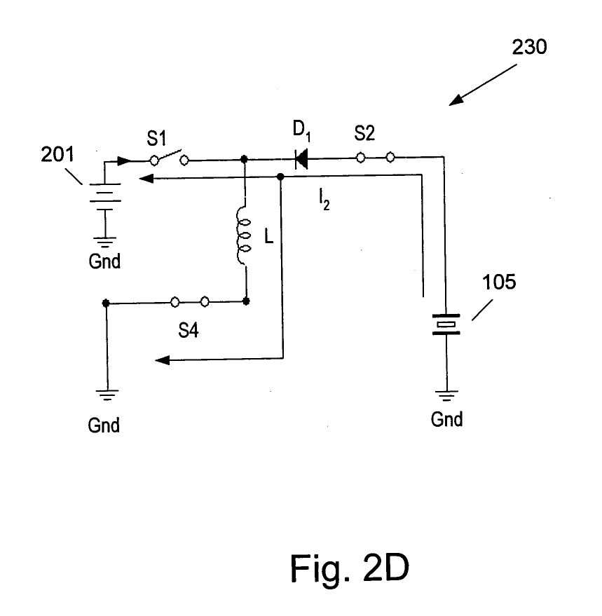

FIG. 2A is an exemplary circuitry 200 of a low-power piezoelectric driver having an increased efficiency and gain, and having relatively low power consumption, according to an embodiment of the present invention. According to this example, the piezoelectric element is a speaker, but this should not limit the invention, as the piezoelectric element can be of other types. An input signal 203 is supplied into a comparator 210 and its voltage value compared to the voltage level (or a predefined portion thereof) of piezoelectric speaker 105 (it should be noted that the input voltage level may be 0.1V peak to peak, while the present voltage level over the piezoelectric element may be, for example, 20V, therefore a voltage divider 131 is generally necessary). A switching control unit 205 receives an output signal 204 from said comparator 210 indicating the comparison result, and closes or opens switches S₁, S₂, S₃ and S₄, accordingly.

If, for example, the comparator indicates that the level of the input signal 203 is higher than the voltage 132 which provides indication to the voltage over piezoelectric speaker 105, the switching control unit initially closes switches S₁, S₃ and S₄ and opens switch S₂. The resulting circuit 210 following said setting of switches is shown in FIG. 2B. As seen in FIG. 2B, the current flows from the battery through inductor L (e.g., L=10 μH) to the ground as shown, and as a result said inductor L is charged. Since the current I that flows through inductor L grows gradually with time, the time period in which switch S₄ is closed determines the energy stored (accumulated) in said inductor L. Such energy can be calculated by the following equation: Energy_{L}=0.5·I²·L.

After a certain time t₁, the switching control unit 205 opens switch S₄, thereby forming an LC (Inductor-Capacitor) circuit 220, as shown in FIG. 2C. Following the opening of S₄, inductor L charges the piezoelectric element (having a capacitance of, for example, 10 nF-100 nF) 105, and the energy that was stored in said inductor L is transferred to said capacitor (except for the energy loss due to non-ideal characteristics of said inductor L and said piezoelectric capacitor). Switch S₄ remains closed during time period t₂, until the end of period P. The time period t₁ is determined by the control unit based on the input signal voltage, the voltage on the piezoelectric element and the electronic characteristics (L, C, R) of the circuit components, for example, t₁=L/R×Ln(V₀/(V₀₋(2×R×C×ΔV×Vpe/L)), wherein V₀ represents a certain constant, Vpe represents the voltage over the piezoelectric element, L is the inductance of the inductor, R represents the passive resistance of the circuit components, C represents the capacitance of the piezoelectric element, and ΔV represents the comparator output. At the end of period P, the procedure continues by an additional comparison between the input signal and the level 132. If, again, the voltage over the piezoelectric element is found to be below necessary, the same procedure repeats. Therefore, by a repetition switching of S₄ ON and OFF in a predefined duty cycle which is defined by t₁ and t₂, the piezoelectric element is charged to a required voltage level (the rate of charging depends on the values of the piezoelectric capacitor 105 and inductor L). Diode D₂ ensures that the piezoelectric element 105 is not discharged when switch S₄ (and S₃) is closed. By this way, the piezoelectric element 105 is charged gradually: during period t₁ inductor L is charged from battery 201, and during period t₂ this charge is transferred to the piezoelectric element. This eliminates the need for using a voltage converter or a “charge pump”, which are usually used in prior art piezoelectric drivers/amplifiers.

If, on the other hand, the comparator indicates that the level of the input signal 203 is lower than of the piezoelectric element voltage indication 132, the switching control unit 205 closes switches S₁, S₂ and S₄ and opens switch S₃. Therefore, an LC circuit 230 as shown on FIG. 2D is formed. Therefore, current I₂, as indicated, gradually increases, transferring current from the piezoelectric element 105 to the inductor L and to the battery. After a time period t₃. S₁ is opened for a period of t₄, and excess charge which has been accumulated within the piezoelectric element is discharged into the inductor L. At the end of period P (as said P≧t₃+t₄), the procedure continues by an additional comparison between the input signal and the level 132. If, again, the voltage over the piezoelectric element is found to be higher than necessary, the same procedure repeats.

It should be noted that when the above described processes are selectively performed (i.e., in each period P, one of the two optional processes, as determined) in a repeated manner, the voltage signal over the piezoelectric element on one hand has a high peak to peak voltage (e.g., 30V p-p), while the energy loss is significantly reduced.

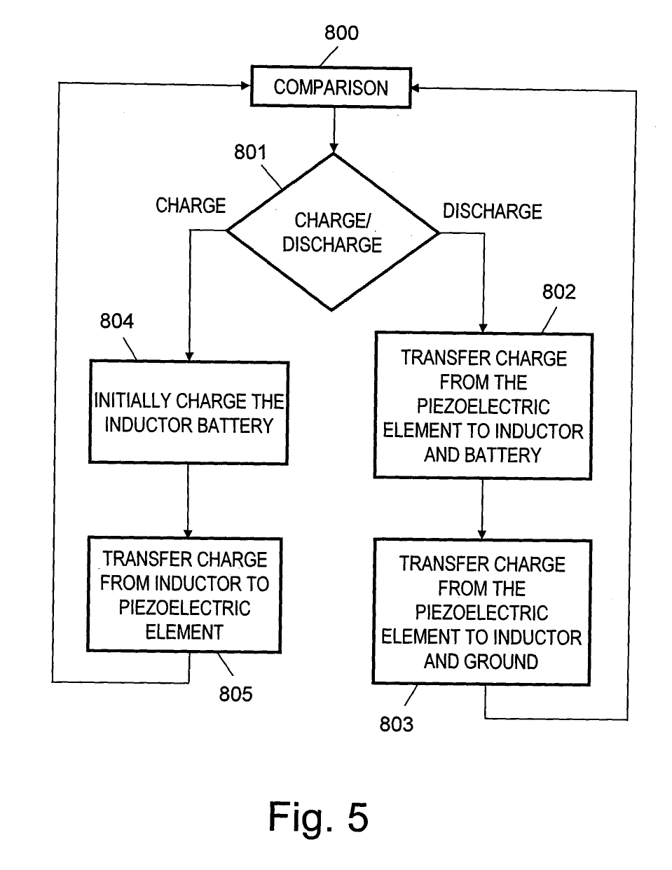

FIG. 5 is a flow chart which generally describes the method of the invention in an exemplary circuit in which the piezoelectric element operates on positive voltage (e.g. 0V-60Vp-p). In step 800, the input signal is compared with a voltage signal which provides indication to the level of the voltage on the piezoelectric element. The comparison result is provided into the switching control unit, which in step 801 determines, based on the result as conveyed from the comparator 800, as to whether a charge or discharge of the piezoelectric element is necessary. If a necessity for charging the piezoelectric element is determined, the method continues to step 804. In step 804, the switching control unit provides control to the switches which results in charging the inductor L from the battery, during a period of t₁. Later on, when t₁ passes, the method continues to step 805. In step 805, the switching control unit issues a setting to the switches, which causes transfer of charge from the conductor L to the piezoelectric element during time t₂. As previously mentioned P≧t₁+t₂, and the period P is significantly shorter than the shortest period that relates to the frequencies expected in the input signal. At the end of step 805, the method returns to step 800.

Alternatively, if a necessity for discharging the piezoelectric element is determined in step 801, the method continues to step 802. In step 802, the switching control unit provides control to the switches which results in transfer of charge from the piezoelectric element to the battery and inductor L during a period of t₃. Later on, at the end of period t₃, the method continues to step 803. In step 803, the switching control unit issues a setting to the switches that causes transfer of charge from the piezoelectric element to the Inductor L during time t₄. Also here, P≧t₃+t₄, and the period P is significantly shorter than the shortest period that relates to the frequencies expected in the input signal. At the end of step 803, the method returns to step 800.

As previously mentioned, when the voltage on piezoelectric speaker 105 is relatively high (e.g., 30 Vp-p) and the voltage of the input signal 203 is relatively low (e.g., +/−0.1Vp-p), then said voltages are not compared directly by means of comparator 210. It such a case, the voltage of the piezoelectric element 105 is downscaled into a suitable voltage range by means of a voltage divider, and then introduced into input 132. After that, the downscaled voltage of the piezoelectric speaker 105 is compared with the input signal 203.

According to another embodiment of the present invention in which the piezoelectric element operates under both positive and negative voltage (e.g. +/−30Vp-p), circuitry 200 of the low-power piezoelectric driver is implemented as described above. However, the method of setting the switched S₁, S₂, S₃ and S₄ is as follows. Immediately at the beginning of each period P, the comparator compares between the present voltage level over the piezoelectric element (or a division thereof) and the input signal and the result is conveyed to the switching control unit according to the following guidelines:
(i) If, for example, the comparator indicates that the level of the input signal 203 is positive and is higher than the voltage 132 which indicates the voltage over piezoelectric speaker 105, the switching control unit initially closes switches S₁, S₃ and S₄ and opens switch S₂, thus the current flows from the battery through inductor L to the ground as shown, and as a result said inductor L is charged. After a certain time t₁, the switching control unit opens switch S₄, thereby forming an LC circuit in which inductor L charges the piezoelectric element and the energy that was stored in said inductor L is transferred to said capacitor (except for the energy loss due to non-ideal characteristics of said inductor L and said piezoelectric capacitor). Switch S₄ remains closed during time period t₂, until the end of period P. It should be noted that t₁+t₂≦P
(ii) If, for example, the comparator indicates that the level of the input signal 203 is positive and is lower than the voltage 132 which indicates the voltage over piezoelectric speaker 105, the switching control unit initially closes switches S₁ and S₃ and opens switches S₂ and S₄ thus the current flows from the piezoelectric element to the battery. After a certain time t₃, the switching control unit opens switch S₁, thereby stopping the discharge of the piezoelectric element. Switch S₁ remains closed during time period t₄, until the end of period P. It should be noted that t₃+t₄≦P
(iii) If, for example, the comparator indicates that the level of the input signal 203 is negative and is higher than the voltage 132 which indicates that the piezoelectric speaker shall be charged by a negative charge, the switching control unit initially closes switches S₁, S₂ and S₄ and opens switch S₃, thus the current flows from the battery through inductor L to the ground. After a certain time t₅, the switching control unit opens switch S₁, thereby diode D₁ opens and the voltage on the piezoelectric element is negatively increased. Switch S₁ remains opened during time period t₆, until the end of period P. It should be noted that t₅+t₆≦P.
(iv) If, for example, the comparator indicates that the level of the input signal 203 is negative and is lower than the voltage 132 which indicates the negative charge in the piezoelectric element shall be discharged, the switching control unit initially closes switches S₃ and S₄ and opens switches S₁ S₂, thus the current flows from the piezoelectric element to the ground. After a certain time t₇, the switching control unit opens switch S₃ or S₄ thereby stopping the discharge of the piezoelectric element. Switch S₃ or S₄ remains opened during time period t₈, until the end of period P. It should be noted that t₇+t₈≦P.

According to another embodiment, circuitry 200 of the low-power piezoelectric driver is implemented without using diodes D₁ and D₂ (e.g., by switching ON and OFF the switches of circuitry 200 in accordance with the polarity of voltage signals, ensuring by that way the desired direction of the current flow and preventing an undesired discharge of inductor L and of the piezoelectric capacitor).

According to still another embodiment of the present invention, instead of using power source 201, the input signal 203 may be provided to inductor L for charging it to a predefined value. In still another option, the voltage of the signal provided to said inductor L may be a portion of the voltage of said input signal 203, or an amplification thereof.

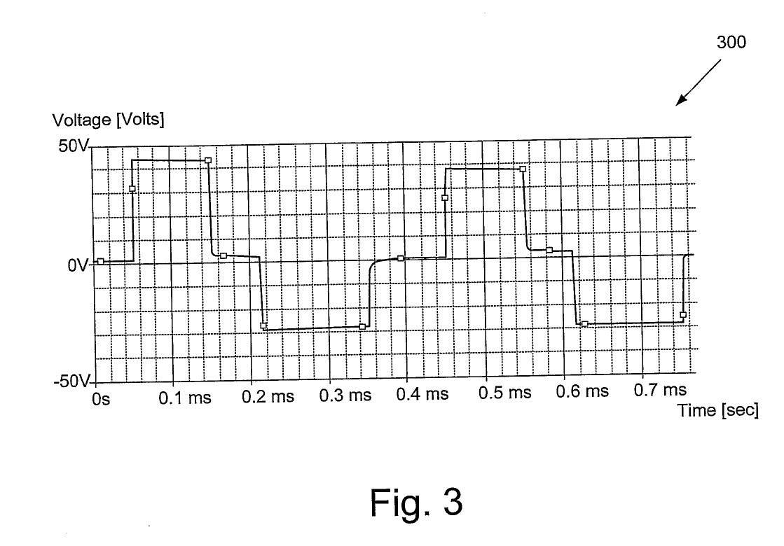

FIG. 3 is an exemplary graph 300 showing the voltage amplitude on piezoelectric element 105, when the voltage of input signal 203 (FIG. 2A) is a sine signal and a relatively low clock rate control signals (control signals having a switching frequency that is only 4 times higher than the input signal frequency) are provided to the switches of the circuitry 200. In this example, the amplitude of the input voltage of power source 201 equals 3 Volts, and the voltage amplitude of piezoelectric speaker 105 changes between −30 Volts and +30 Volts. By implementing circuitry 200 of FIG. 2, a “charge pump” or a voltage converter is virtually created, since the maximum and minimum voltage levels supplied to piezoelectric speaker 105 are determined by switching.

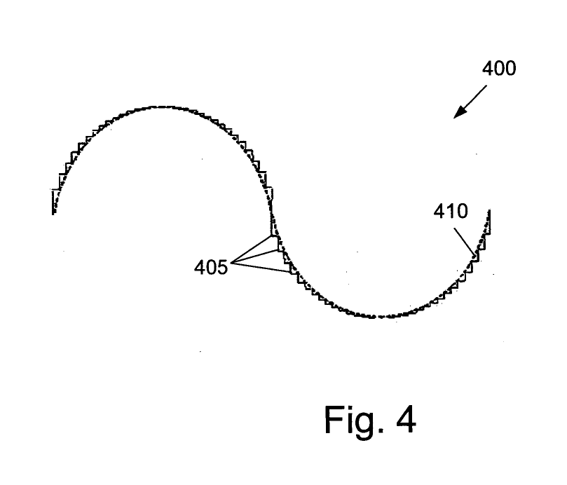

FIG. 4 is an exemplary graph 400 showing the voltage amplitude on piezoelectric speaker 105 (FIG. 2A) when the voltage of input signal 203 (FIG. 2A) is a sine signal, and a high clock rate control signals (control signals having a high switching frequency—i.e., short P) are provided to switches of the circuitry 200 (FIG. 2A), according to an embodiment of the present invention. According to this embodiment, for avoiding noise and distortion of an output audio signal of circuitry 200, the switching frequency has to be much higher than the frequency of an audio signal (e.g., the switching frequency may be, for example, 300 KHz for an audio signal of 100 Hz-10 KHz). The high-frequency noise (illustrated as small pulses 405 riding on sine wave 410), resulting from the high-frequency switching, is out of the hearing range, and thus cannot be heard by a person using such piezoelectric speaker 105.

It has been found by the inventors that a circuit according to the invention which uses a 3.2V battery, and provides 60Vp-p to a piezoelectric speaker consumes only 6 mA from the battery. On the other hand, typical prior art circuits which use a 3.2 volts battery and provide 60Vp-p to a similar piezoelectric speaker consume between 30 mA to 50 mA. Therefore, according to this example, the circuit of the present invention provides saving of between 80% and 90% of the battery energy.

It should be noted that switching control unit 205 (FIG. 2A) controls the piezoelectric capacitor charge/discharge time. This can be done, for example, by changing time period tᵢ as explained above, or by changing the frequency (and thus the period P) or the duty cycles of the control signals that are provided to switches S₁, S₂, S₃ and S₄. According to another embodiment of the present invention, for controlling the piezoelectric capacitor charge/discharge time, the switching frequency of the control signal(s) is changed.

The fact that the amplifier of the present invention operates in periods that are significantly shorter than the period of the highest frequency which is included within the input signal essentially eliminates noise in the frequencies of interest (i.e., those within the input signal). In the specific case of using a piezoelectric speaker and providing an audio signal at the input (e.g., 10 Hz-10 KHz), noise having a frequency of 10 times or more (i.e., 100 KHz or more) that appears on the piezoelectric element will not be heard. Therefore, the circuit of the invention essentially does not reduce the quality of the output signal over the piezoelectric element.

The circuits as described herein have been provided as general examples for the purpose of explaining the invention. In practice, the circuits may include additional components, for example components for providing safety measures against transient extreme voltage levels which may harm the circuit components.

It should also be noted that the switches are most preferably semiconductor switches. Furthermore, the battery which has been referred to herein can be replaced by a power supply.

While some embodiments of the invention have been described by way of illustration, it will be apparent that the invention can be put into practice with many modifications, variations and adaptations, and with the use of numerous equivalents or alternative solutions that are within the scope of persons skilled in the art, without departing from the spirit of the invention or exceeding the scope of the claims.

1. A switched low-energy consumption amplifier for a piezoelectric element, which comprises:
a. an inductor, which together with the capacitance of said piezoelectric element forms an LC circuit;
b. a battery connected to said LC circuit;
c. a set of controlled switches capable of connecting and disconnecting circuit components at a rate which is significantly higher than the frequency of an input signal to said circuit;
d. a comparator for receiving an input signal, comparing a present voltage value of the input signal with a present voltage value over said piezoelectric element or a part thereof, and conveying an indication regarding said comparison to a switching control unit; and
e. a switching control unit for receiving said indication from said comparator, and determining repeatedly every period P, which is significantly shorter than the period of the highest frequency included within said input signal, whether the piezoelectric element should be charged or discharged, and accordingly providing a control signal to each of said controlled switches with a certain duty cycle of P, thereby causing energy transfer from the piezoelectric element to the inductor and/or battery, or from the battery and/or inductor to the piezoelectric element, thereby retaining the energy within the amplifier circuit;
wherein:
f. If it is determined by said switching control unit that the piezoelectric element should be charged, initially providing a first set of control signals to said controlled switches which results in charging of the inductor from said battery during a period t₁, followed by the providing of a second set of control signals which results in transfer of said charge during a period t₂ from the inductor to said piezoelectric element, and wherein t₁+t₂≦P; or
g. If it is found by said switching control unit that the piezoelectric element should be discharged, initially providing a third set of control signals to said controlled switches which results in transfer of charge from said piezoelectric element to the inductor and battery during a period t₃, followed by the providing of a fourth set of control signals which results in transfer of charge during a period t₄ from the piezoelectric element to the inductor only, and wherein t₃+t₄≦P.

2. (canceled)

3. Amplifier according to claim 1, wherein:
a. If it is determined by said switching control unit that the piezoelectric element should be negatively charged, initially providing a 5^{th} set of control signals to said controlled switches which results in transfer of charge from the battery to the inductor during a period t₅, followed by the providing of a 6^{th} set of control signals which results in a transfer of charge from the piezoelectric element to the inductor during a time period t₆, and wherein t₅+t₆≦P; or
b. If it is determined by said switching control unit that the piezoelectric element should be negatively discharged, initially providing an 7^{th} set of control signals to said controlled switches which results in transfer of charge from the piezoelectric element to the ground a period t₇, followed by the providing of an 8^{th} set of control signals which results in terminating a transfer of charge from the piezoelectric element to the ground during a time period t₈, and wherein t₇+t₈≦P.

4. Amplifier according to claim 1, wherein the piezoelectric element is a piezoelectric speaker.

5. Amplifier according to claim 1, wherein the period P is at least 10 times shorter than the period of the highest frequency included within said input signal.

6. Amplifier according to claim 1, which further comprises diodes.

7. Amplifier according to claim 1, wherein said switches are semiconductor switches.

8. Amplifier according to claim 1, which further comprises safety measures against transient extreme voltage levels which may harm the circuit components.
